(19) United States
(12) Patent Application Publication
(10) Pub. No.: US 2025/0133715 A1
(43) Pub. Date: Apr. 24, 2025

(54) SEMICONDUCTOR DEVICES WITH GATE EXTENSIONS AND METHODS OF FABRICATING THE SAME

(71) Applicant: Taiwan Semiconductor Manufacturing Company, Ltd., Hsinchu (TW)

(72) Inventors: Yu-Fang Chiu, Hsinchu (TW); Anhao Cheng, Hsinchu (TW); Yen-Liang Lin, Hsinchu (TW); Ru-Shang Hsiao, Hsinchu (TW)

(73) Assignee: Taiwan Semiconductor Manufacturing Company, Ltd., Hsinchu (TW)

(21) Appl. No.: 18/490,919

(22) Filed: Oct. 20, 2023

(51) Int. Cl. H10B 10/00; H01L 29/06; H01L 29/66; H01L 29/78

(52) U.S. Cl. CPC H10B 10/12; H10D 30/024; H10D 30/6211; H10D 62/115; H10D 64/017

(57) ABSTRACT

A semiconductor structure includes a first isolation structure and a second isolation structure disposed in a substrate. The semiconductor structure includes a doped region interposed between the first isolation structure and the second isolation structure in the substrate. The semiconductor structure includes a gate structure disposed over the doped region. The semiconductor structure includes a first gate extension protruding from the gate structure into the first isolation structure, where the first gate extension has a first depth measured from a top surface of the substrate. The semiconductor structure further includes a second gate extension protruding from the gate structure into the second isolation structure, where the second gate extension has a second depth that is different from the first depth.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components or devices to be integrated into a given area. While existing strategies of integrating devices in a static random-access memory (SRAM) cell have been generally adequate, they have not been entirely satisfactory in all aspects. For example, it remains a challenge to meet various performance targets, such as improved read margin and write margin, in integrated SRAM devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a flowchart of an example method of fabricating a semiconductor device, in accordance with some embodiments.

FIGS. 2A, 2B, 3, 4, 5A, 5B, 5C, 6, 7A, 7B, 8, 9, 10, 11, 12A, 12B, 13A, and 13B each illustrate a first cross-sectional view of an example semiconductor device at intermediate stages of the example method of FIG. 1, in accordance with some embodiments.

FIGS. 14 and 15 each illustrate a second cross-sectional view of the example semiconductor device at intermediate stages of the example method of FIG. 1, in accordance with some embodiments.

FIG. 16 illustrates an example circuit diagram of an example memory cell, in accordance with some embodiments.

FIG. 17 illustrates an example layout of the example memory cell corresponding to the circuit diagram of FIG. 16, in accordance with some embodiments.

FIGS. 18, 19, 20, and 21 each illustrate a cross-sectional view of the example memory cell along line A-A′ of the example layout in FIG. 17, in accordance with some embodiments.

FIG. 22 illustrates an example circuit diagram of an example memory cell, in accordance with some embodiments.

FIG. 23 illustrates an example layout of the example memory cell corresponding to the circuit diagram of FIG. 22, in accordance with some embodiments.

FIGS. 24, 26, 26, and 27 each illustrate a cross-sectional view of the example memory cell along line A-A′ of the example layout in FIG. 23, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

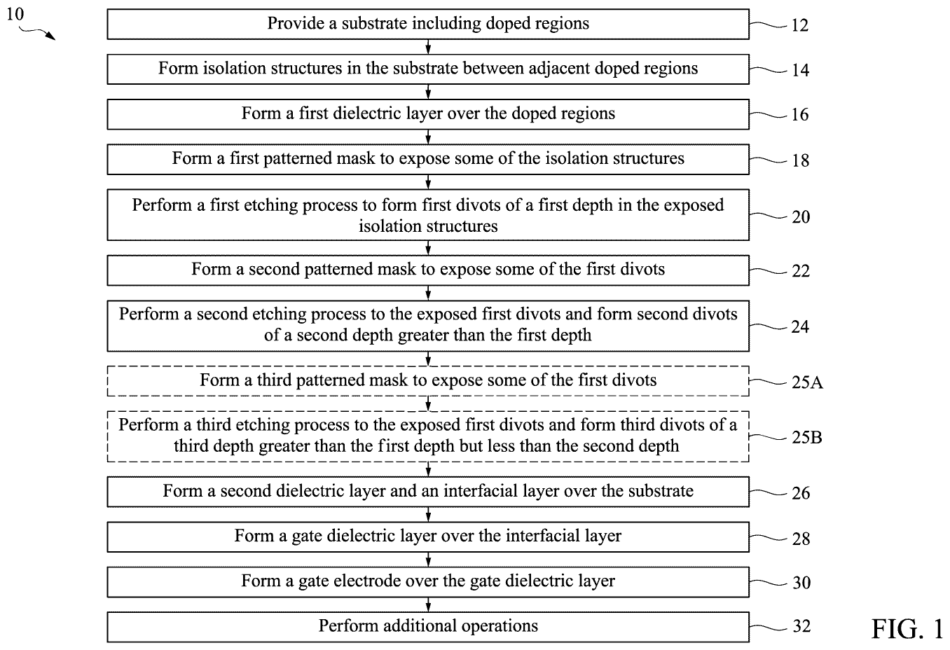

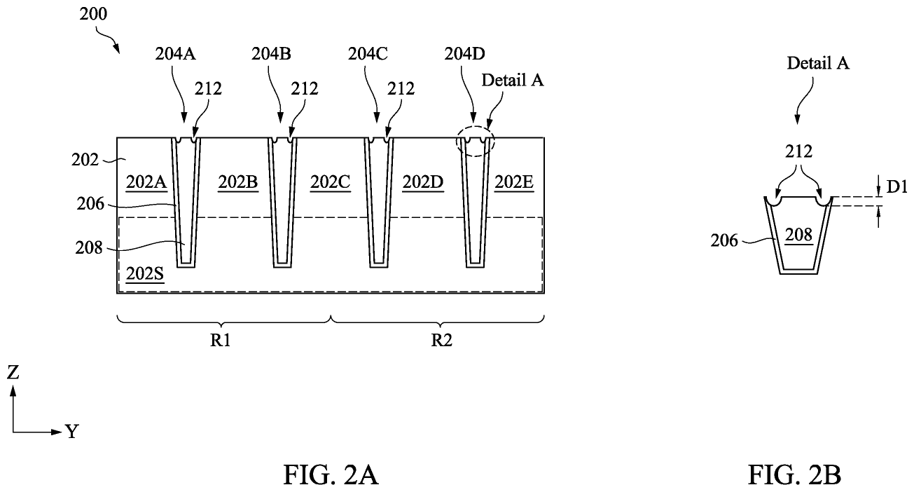

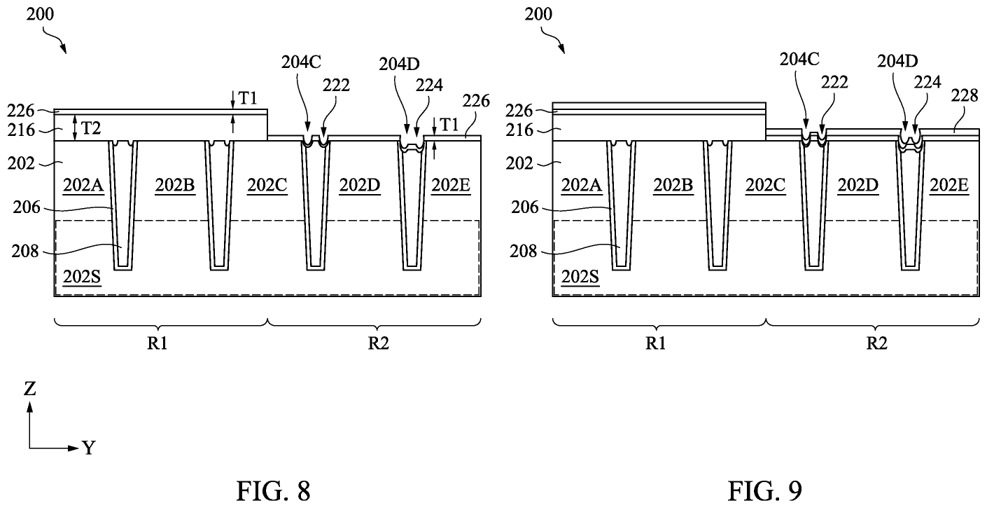

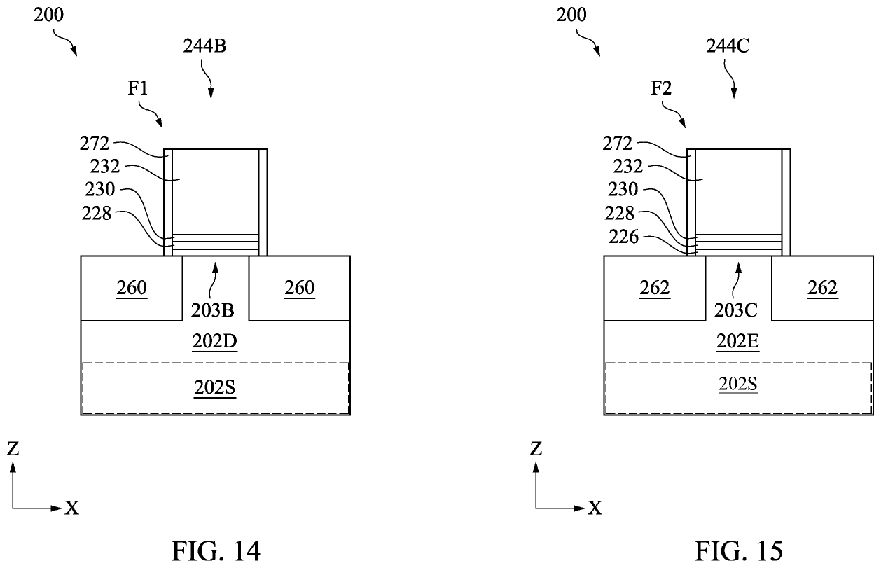

FIG. 1 illustrates a flowchart of a method 10 to form a semiconductor device 200, according to one or more embodiments of the present disclosure. In some embodiments, operations of the method 10 may be associated with cross-sectional views of the semiconductor device 200 in a plane defined by axes Y and Z at various fabrication stages as depicted in FIGS. 2A-13B and cross-sectional view of the semiconductor device 200 in a plane defined by axes X and Z at various fabrication stages as depicted in FIGS. 14 and 15. It is noted that the method 10 is merely an example and is not intended to limit the present disclosure. Accordingly, it should be understood that additional operations may be provided before, during, and after the method 10 of FIG. 1, and that some other operations may only be briefly described herein.

Referring to FIGS. 1, 2A, and 2B, a substrate 202 is provided for the semiconductor device 200 at operation 12. The substrate 202 may include a semiconductor substrate, such as a bulk semiconductor, a semiconductor-on-insulator (SOI) substrate, or the like, which may be doped (e.g., with a p-type or an n-type dopant) or undoped. The substrate 202 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 202 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments, the substrate 202 includes a plurality of doped regions (or doped wells) 202A, 202B, 202B, 202C, 202D, and 202E (collectively referred to as doped regions 202A-202E), disposed over a bottom region 202S, which is enclosed by dashed lines for illustration purposes only. As the doped regions 202A-202E are configured to provide active devices, such as transistors in a memory device, the doped regions 202A-202E are alternatively referred to as active regions 202A-202E. The doped regions 202A-202E may be formed by performing a series of patterning and doping processes. For example, a patterned mask layer (not depicted) may be formed over the substrate 202 to expose portions of the underlying substrate 202. The patterned mask layer may include a photoresist material that can be patterned using photolithography techniques. Generally, photolithography techniques utilize the photoresist material that is deposited, irradiated (or exposed), and developed to remove a portion of the photoresist material. The remaining photoresist material, which forms the patterned mask layer, protects the underlying material from subsequent processing steps, such as doping or etching. The patterned mask layer may alternatively include a dielectric material, such as an oxide, that is patterned by the photolithography techniques, for example.

The patterned mask is subsequently used to dope the exposed portion(s) of the substrate 202 and form the doped regions 202A-202E. The exposed portions of the substrate 202 may be doped by an implantation process, a diffusion process, or the like. In some embodiments, subsets of the doped regions 202A-202E are configured to provide semiconductor devices (e.g., transistors) of different conductivity types. For example, the doped region 202C may include an n-type dopant to form n-type wells (or n-wells) for p-type devices (e.g., a pull-up transistor in an SRAM cell), and the doped regions 202A, 202B, 202D, and 202E may each include a p-type dopant to form p-type wells (or p-wells) for n-type devices (e.g., a pull-down transistor an a pass-gate transistor in an SRAM cell). In some embodiments, the doped regions 202A-202E include the same dopant (n-type or p-type) to provide devices of the same conductivity type. Example p-type dopants may include boron, gallium, indium, the like, or combinations thereof, and example n-type dopants may include phosphorus, arsenic, the like, or combinations thereof.

As depicted, the doped regions 202A-202E are formed in an upper portion of the substrate 202 such that the bottom region 202S remains undoped or substantially undoped. In other words, the doped regions 202A-202E do not extend through an entirety of the substrate 202. A depth of each doped regions 202A-202E may be controlled during the doping process by adjusting parameters such as implantation energy. In some embodiments, the doped regions 202A-202E having the same type(s) of dopants may be doped with different dopant concentrations.

In some embodiments, after forming the doped regions 202A-202E, a mask layer, including a pad oxide layer and an overlying pad nitride layer, for example, is formed over the substrate 202 and configured to protect the underlying material during the subsequent processing steps. The pad oxide layer may be a thin film including silicon oxide formed, for example, using a thermal oxidation process, a chemical oxidation process, chemical vapor deposition (CVD), the like, or combinations thereof. The pad oxide layer may act as an adhesion layer between the substrate 202 and the overlying pad nitride layer. In some embodiments, the pad nitride layer is formed of silicon nitride, silicon oxynitride, silicon carbonitride, the like, or combinations thereof. The pad nitride layer may be formed using CVD, low-pressure CVD (LPCVD), plasma-enhanced CVD (PECVD), the like, or combinations thereof.

Still referring to FIGS. 1, 2A, and 2B, a plurality of isolation structures 204A, 204B, 204C, and 204D (collectively referred to as the isolation structures 204) are formed in the substrate 202 at operation 14, where each of the isolation structures 204 separates two adjacent doped regions 202A-202E along the lateral direction (e.g., along the Y axis) and extends vertically (e.g., along the Z axis) past a bottom surface of each of the doped regions 202A-202E. In other words, the isolation structures 204 penetrates the bottom region 202S of the substrate 202 such that the adjacent doped regions 202A-202E are electrically isolated from one another.

In some embodiments, the isolation structure 204 has a multi-layered structure and includes a dielectric layer 208 over a dielectric layer 206, where the dielectric layers 206 and 208 have different compositions. In some embodiments, the dielectric layers 206 and 208 each include an oxide, such as silicon oxide (SiO and/or SiO2), a nitride, the like, or combinations thereof. In some embodiments, the isolation structures 204 has a single-layer structure. In some embodiments, the isolation structure 204 includes a shallow trench isolation (STI) structure.

The isolation structures may be formed by patterning the mask layer to expose portions of the substrate 202 between adjacent doped regions 202A-202E. The mask layer may be patterned by photolithography process similar to that described above with respect to doping the substrate 202, followed by an etching process using the patterned mask layer as an etch mask to form trenches (not depicted) penetrating the substrate 202. The etching process may include dry etching, wet etching, reactive ion etching (RIE), the like, or combinations thereof. Subsequently, the dielectric layers 206 and 208 may each be deposited in the trenches by any suitable process, such as high-density plasma CVD (HDPCVD), flowable CVD (FCVD) (e.g., a CVD-based material deposition in a remote plasma system, followed by an annealing or curing process to densify the deposited material into another material, such as an oxide), spin coating, the like, or combinations thereof. Other dielectric materials and/or other formation processes may be used to form the isolation structures 204.

A planarization process, such as a chemical-mechanical polish/planarization (CMP) process, may remove any excess dielectric materials of the dielectric layers 206 and 208. The patterned mask layer over the top surface of the substrate 202 may also be removed by the planarization process. Referring to Detail A depicted in FIG. 2B, during the planarization process, portions of the isolation structures 204 near an interface between each isolation structure 204 and an adjacent doped region may be inadvertently consumed (or over-etched) to form divots (or recesses) 212. In this regard, a pair of the divots 212 may be present in each of the isolation structures 204A-204D. In some embodiments, each divot 212 is formed in both the dielectric layers 206 and 208. The divots 212 may each be defined by a depth D1 measured from a top surface of the substrate 202 (e.g., a top surface of the doped regions 202A-202E). In some examples, the depth D1 may be about 0.1 nm to about 0.5 nm. In some examples, the depth D1 may be less than about 0.1 nm and negligible with respect to a depth of the isolation structure 204. In some examples, the divots 212 may not formed by this planarization process.

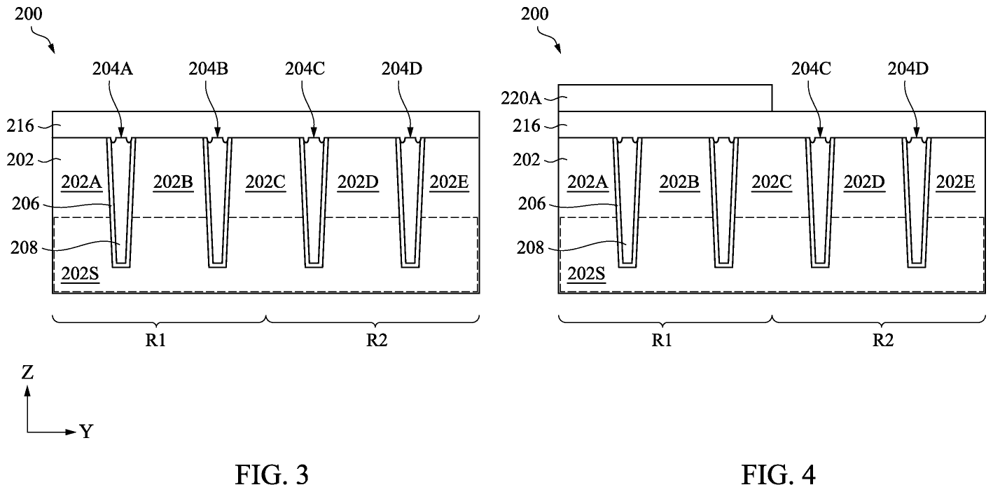

Referring to FIGS. 1 and 3, a dielectric layer 216 is formed over the substrate 202 at operation 16, thereby filling the divots 212. The dielectric layer 216 may include an oxide material, such as SiO and/or SiO₂, and may be configured as a gate oxide material for I/O devices provided in a device region R1 of the substrate 202, which is disposed adjacent a device region R2 configured to provide core devices, including memory devices such as SRAM devices. The dielectric layer 216 may be formed by any suitable process, such as CVD, FCVD, spin coating, the like, or combinations thereof.

Referring to FIGS. 1 and 4, a patterned mask 220 is formed over the substrate 202 to expose a portion of the dielectric layer 216 in the device region R2 at operation 18. The patterned mask 220A may include a photoresist material and patterned using the photolithographic technique described in detail above with respect to patterning the substrate 202. For illustration purposes only, the patterned mask 220A is depicted to cover the isolation structures 204A and 204B and exposes the isolation structures 204C and 204D.

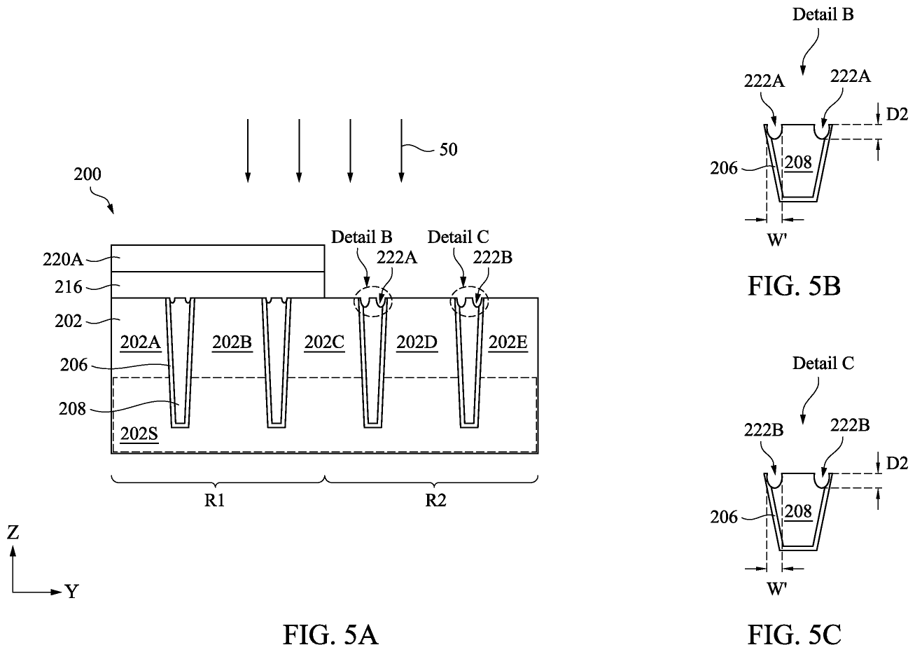

Subsequently, referring to FIGS. 1, 5A, 5B, and 5C, a first etching process 50 is applied to the semiconductor device 200 at operation 20. The first etching process 50 is configured to remove the exposed portion of the dielectric layer 216 from the device region R2, which includes the isolation structures 204C and 204D and at least portions of the doped regions 202C, 202D, and 202E. The first etching process 50 may include any suitable process, such as wet etching, dry etching, or the like. In the present embodiments, the first etching process 50 includes a wet etching process implemented using a wet etchant that selectively removes both the dielectric layer 216 and the isolation structure 204 (e.g., the dielectric layers 206 and 208) without removing, or substantially removing, the semiconductor material of the doped regions 202C-202E in the device region R2. In some embodiments, the first etching process 50 is implemented using a hydrofluoric acid (HF)-containing wet etchant, such as dilute HF (DHF). After performing the first etching process 50, the patterned mask 220A is removed from the semiconductor device 200 by any suitable method, such as plasma ashing or resist stripping.

As depicted, the first etching process 50 is controlled to remove portions of the dielectric layer 216 over the top surface of the substrate 202 as well as portions of the dielectric layer 216 formed in the divots 212, thereby re-exposing the divots 212. In the present embodiments, referring to FIGS. 5B and 5C, subsequent to removing the portions of the dielectric layer 216 from the divots 212, the first etching process 50 is controlled to further remove portions of the exposed isolation structures 204C and 204D exposed in the divots 212, resulting in a first divot 222A (as depicted in Detail B in FIG. 5B) and a second divot 222B (as depicted in Detail C in FIG. 5C), respectively. In some embodiments, a duration of the first etching process 50 is extended, for example, to form the first divot 222A and the second divot 222B (collectively referred to as the divots 222) after removing the dielectric layer 216. For example, the first etching process 50 is allowed to continue after removing the dielectric layer 216, while other etching parameters, such as the type and concentration of the wet etchant, remain the same. The divots 222 can each be defined by a depth D2 measured from a top surface of the substrate 202 and a divot width W′ measured across a top opening of the divot 222, where the depth D2 is greater than the depth D1. In some embodiments, the depth D2 is about 0.1 nm to about 1.5 nm and the divot width W′ is about 20 nm to about 25 nm, though the present disclosure is not limited to such ranges. In one example, the depth D1 may be about 0.1 nm and the depth D2 may be about 0.5 nm. In some embodiments, the first etching process 50 may not deepen or enlarge the divots 212, so the depth D2 of the first divot 222A and the second divot 222B is similar to or the same as that of the divots 212. For embodiments in which the divots 212 are not observed, the first etching process 50 may remove corner portions of the exposed isolation structures 204C and 204D.

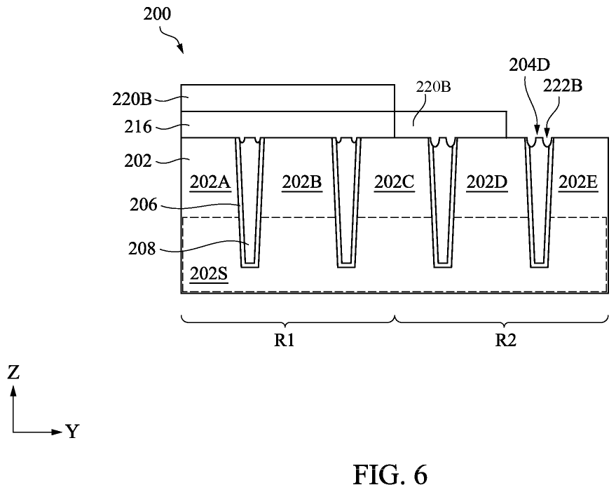

Referring to FIGS. 1 and 6, a patterned mask 220B is formed over the device region R1 and a portion of the device region R2 at operation 22.

The patterned mask 220B may be similar to the patterned mask 220A and include a patternable photoresist material. The patterned mask 220B may be formed by a process similar to that of patterning the substrate 202. As depicted, portions of the patterned mask 220B fill the first divots 222A but not the second divots 222B. In other words, the second divots 222B are exposed by the patterned mask 220B.

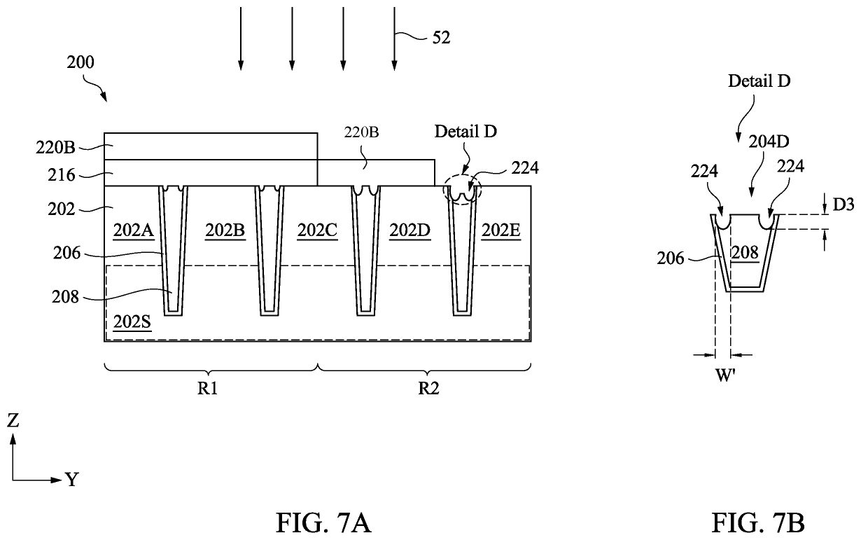

Referring to FIGS. 1, 7A, and 7B, a second etching process 52 is applied to the semiconductor device 200 at operation 24 to selectively deepen the second divots 222B, resulting in divots 224 in the isolation structure 204D.

The second etching process 52 is configured to remove portions of the isolation structures 204 exposed by the patterned mask 220B including, for example, the isolation structures 204C and 204D. The second etching process 52 may be similar to the first etching process 50 and may include any suitable process, such as a wet etching, a dry etching, or the like. In the present embodiments, the second etching process 52 includes a wet etching process implemented using a wet etchant similar to or the same as that used for the first etching process 50. An example wet etchant that can be implemented for both the first etching process 50 and the second etching process 52 includes hydrofluoric acid (HF), such as dilute HF (DHF). In some embodiments, the first etching process 50 and the second etching process 52 are implemented using different etchants (e.g., different wet etchants). After performing the second etching process 52, the patterned mask 220B is removed from the semiconductor device 200 by any suitable method, such as plasma ashing or resist stripping.

Referring to FIGS. 7A and 7B, the second etching process 52 selectively removes portions of isolation structure 204D (e.g., the dielectric layers 206 and 208) exposed in the second divots 222B without removing, or substantially removing, the materials of the doped regions 202D and 202E, resulting in divots 224 in the isolation structure 204D. As depicted, the divots 224 can each be defined by a depth D3 measured from the top surface of the substrate 202 and the divot width W′ measured across a top opening of the divot, where the depth D3 is greater than the depth D2. In some embodiments, the depth D3 ranges from about 2.5 nm to about 5.5 nm and the divot width W′ ranges from about 20 nm to about 25 nm, though the present disclosure is not limited to such ranges. In some embodiments, a ratio of the depth D3 to the depth D2 is about 1.7 to about 55, though the present disclosure is not limited to such a range. In some embodiments, the divot width W′ remains relatively constant after performing the second etching process 52.

In some embodiments, if the first etching process 50 and the second etching process 52 are implemented using the same wet etchant, such as HF (e.g., DHF), and the duration of both etching processes are kept substantially the same, then the HF used for the second etching process 52 is configured to have a greater concentration than that used for the first etching process 50. In some embodiments, if the first etching process 50 and the second etching process 52 are implemented using the same wet etchant, such as HF, having substantially the same concentration, then the second etching process 52 is implemented for a longer duration than the first etching process 50. Whether the first etching process 50 and the second etching process 52 are varied based on the concentration of the wet etchant or on the duration of the etching process, each of the first etching process 50 and the second etching process 52 is controlled to ensure that the depth D3 is greater than the depth D2 according to the embodiments provided herein. As will be discussed in detail below, a difference between the depths D2 and D3 corresponds to a difference in channel width of respective gate structure formed over the doped regions 202D and 202E.

In some embodiments, referring to FIG. 1, after removing the patterned mask 220B, another patterned mask (not depicted) may be formed over the divots 224 at operation 25A to expose some of the first divots 222A (not depicted). Subsequently, a third etching process (not depicted) may be performed at operation 25B to deepen the exposed first divots 222A to a depth that is different from the depths D2 and D3. In some examples, such a depth may be within a range similar to that of the depth D3. In some examples, such a depth may be greater than the depth D2 but less than the depth D3. Accordingly, operations 20-25B provide methods of forming divots of three different depths. In some embodiments, operations 25A and 25B are omitted from the method 10.

Referring to FIGS. 1, 8, and 9, a dielectric layer 226 and an interfacial layer 228 are formed over the device regions R1 and R2 at operation 26, thereby at least partially filling the divots 222 in the device region R1 and 224 in the device region R2.

The dielectric layer 226 may include a gate oxide material having a composition similar to or the same as that of the dielectric layer 216, which is discussed in detail above. The interfacial layer 228 may also include an oxide material, such as silicon oxide (SiO and/or SiO₂), formed conformally over the substrate 202 in both device regions R1 and R2. Accordingly, the dielectric layer 226 and the interfacial layer 228 may be collectively referred to as an oxide layer. In some embodiments, the dielectric layer 216, the dielectric layer 226, and the interfacial layer 228 have the same composition and all include silicon oxide. In some embodiments, the dielectric layer 226 is formed over the substrate 202 to a thickness T1 that is less than a thickness T2 of the dielectric layer 216. In some embodiments, the dielectric layer 226 is omitted from the semiconductor device 200. The dielectric layer 226 and the interfacial layer 228 may each be conformally deposited by any suitable process, such as thermal oxidation, chemical oxidation, CVD, atomic layer deposition (ALD), physical vapor deposition (PVD), the like, or combinations thereof.

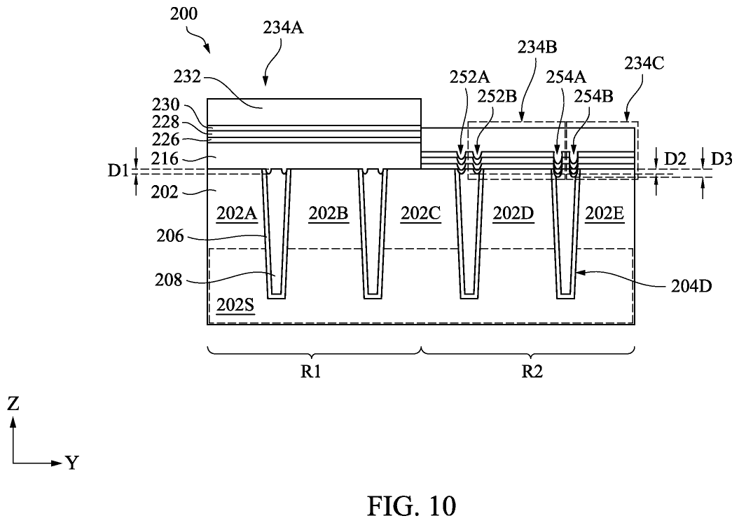

Referring to FIGS. 1 and 10, a gate dielectric layer 230 is formed over the interfacial layer 228 at operation 28.

In the present embodiments, the gate dielectric layer 230 includes a high-k dielectric material having a dielectric constant, or k value, greater than about 3.9, which is the dielectric constant of silicon dioxide (SiO₂). In this regard, the gate dielectric layer 230 may be alternatively referred to as a high-k dielectric layer 230. In some examples, the high-k dielectric material may have a dielectric constant of greater than about 7.0. The high-k dielectric material may include a metal oxide or a metal silicate of Hf, Al, Zr, La, Mg, Ba, Ti, Pb, the like, or combinations thereof. In some embodiments, the gate dielectric layer 230 alternatively or additionally includes silicon oxide, silicon nitride, or multilayers thereof. The gate dielectric layer 230 may be formed by any suitable process, such as ALD, CVD, PVD, PECVD, molecular beam deposition (MBD), the like, or combinations thereof.

Still referring to FIGS. 1 and 10, a gate electrode 232 is formed over the gate dielectric layer 230 at operation 30 to complete formation of a first gate structure 234A in the device region R1 and a second gate structure 234B and a third gate structure 234C in the device region R2. In the present embodiments, each of the gate structures 234A-234C engages with subsequently formed source/drain structures in their respective doped regions to form devices, such as transistors.

In some embodiments, the gate electrode 232 includes a conductive material (e.g., a metal), such as polysilicon, tungsten (W), copper (Cu), ruthenium (Ru), aluminum (Al), gold (Au), cobalt (Co), the like, or combinations thereof. In some embodiments, the gate structures 234A-234C each further include one or more work function metal layers (not depicted) disposed between the gate dielectric layer 230 and the gate electrode 232. The work function metal layer may include any suitable conductive material, such as TiN, TaN, Ru, Mo, Al, WN, ZrSi₂, MoSi₂, TaSi₂, NiSi₂, Ti, Ag, TaAl, TaAlC, TiAlN, TaC, TaCN, TaSiN, Mn, Zr, the like, or combinations thereof. The work function metal layer(s) may be configured to provide a p-type metal gate structure (PMG) for a p-type device or an n-type metal gate structure (NMG) for an n-type device.

In some embodiments, the gate electrode 232 includes polysilicon and the gate structures 234A-234C are configured as dummy gate structures, which are subsequently replaced with corresponding metal gate structures that each include one or more work function metal layers and a conductive gate electrode after forming other components of the semiconductor device 200, such as source/drain structures in the doped regions 202A-202E.

In some embodiments, still referring to FIG. 10, depending upon a thickness of each of the dielectric layer 226, the interfacial layer 228, and the gate dielectric layer 230, the divots 222 and 224 are at least partially filled by one or more of these layers at operations 26-30 to form a pair of first gate extensions 252A and 252B in the isolation structure 204C and a pair of second gate extensions 254A and 254B in the isolation structure 204D. As the first gate extensions 252A and 252B and the second gate extensions 254A and 254B protrude along the Z axis, they may be alternatively referred to as vertical gate extensions. In the present embodiments, the first gate extensions 252A and 252B extend (or protrude) to below the top surface of the substrate 202 by the depth D2 and the second gate extensions 254A and 254B extend (or protrude) to below the top surface of the substrate 202 by the depth D3. Correspondingly, the first gate extensions 252A and 252B each extend the second gate structure 234B along a sidewall of the doped region 202D by a shorter vertical distance (i.e., the depth D2) than the second gate extensions 254A and 254B each extend the third gate structure 234C along a sidewall of the doped region 202E (i.e., the depth D3).

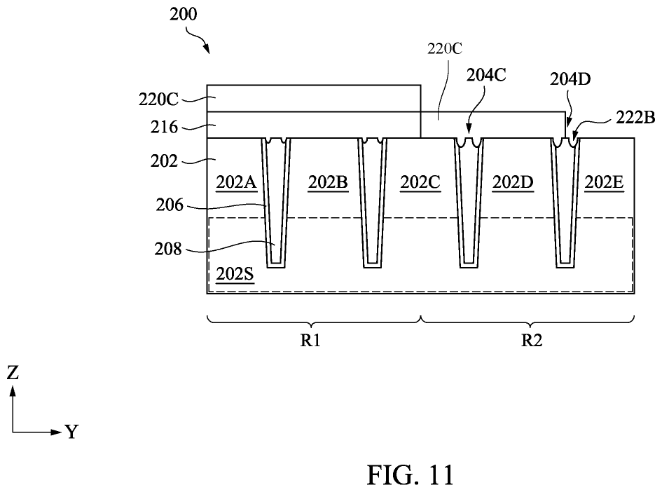

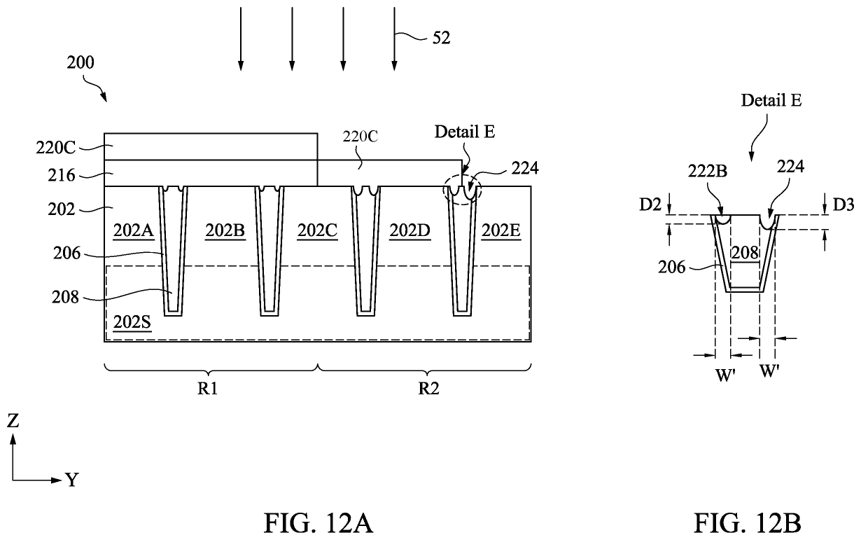

In some embodiments, the method 10 provides processing flexibility with respect to where the second etching process 52 is applied over the semiconductor device 200. For example, referring to FIG. 11, a patterned mask 220C is formed in place of the patterned mask 220B as depicted in FIG. 6 at operation 22. The patterned mask 220C differs from the patterned mask 220B in that the patterned mask 220C extends laterally to cover only one of the second divots 222B formed in the isolation structure 204D. Subsequently, referring to FIGS. 12A and 12B, which depicts the semiconductor device 200 and Detail E, respectively, performing the second etching process 52 at operation 24 selectively deepens only the exposed second divot 222B to form the divot 224 having the depth D3, while the covered second divot 222B remains substantially unaffected by the second etching process 52 (i.e., having the depth D2).

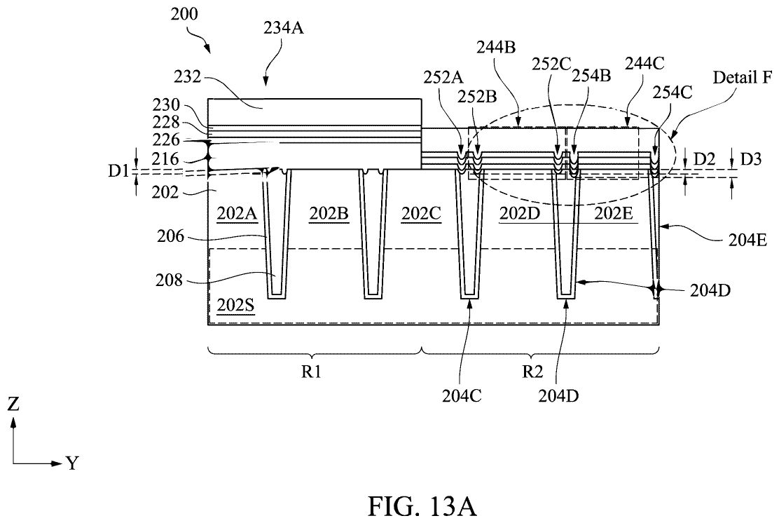

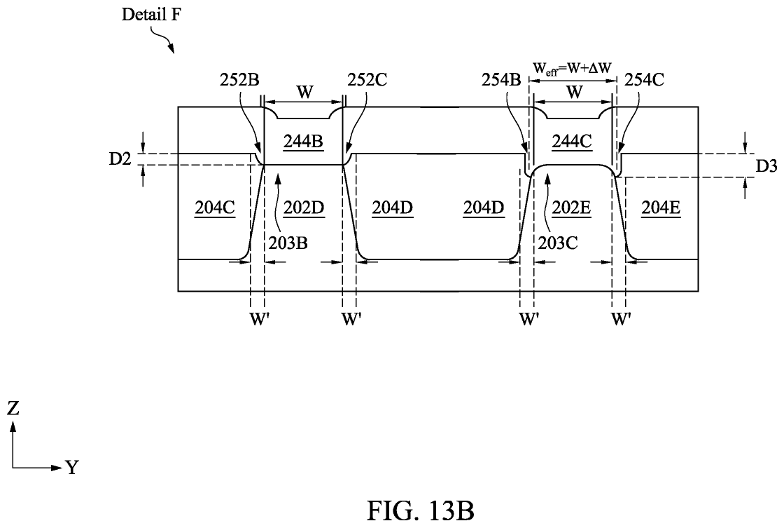

Upon completing operations 26-30, referring to FIG. 13A, the pair of the first gate extensions 252A and 252B are formed in the isolation structure 204C similar to that depicted in FIG. 10, and an additional first gate extension 252C and one of the second gate extensions 254B are formed in the isolation structure 204D, which is a configuration different from that depicted in FIG. 10. In some embodiments, still referring to FIG. 13A, an additional second gate extension 254C is formed in an isolation structure 204E adjacent the doped region 202E during operations 22-30 to correspond to the second gate extension 254B formed in the isolation structure 204D.

Accordingly, referring to FIG. 13B, which depicts Detail F of the semiconductor device 200, the first gate structure 244B engages with the sidewalls of the doped region 202D along the first gate extensions 252B and 252C, while the second gate structure 244C engages with the sidewalls of the doped region 202E along the second gate extensions 254B and 254C. Additionally, as depicted, the first gate structure 244B laterally traverses the doped region 202D along a channel region 203B and the second gate structure 244C laterally traverses the doped region 202E along a channel region 203C, where the channel regions 203B and 203C have substantially the same channel width W measured laterally along the axis Y. In some embodiments, as depicted in FIG. 13B, an effective channel width W_{eff} of the second gate structure 244C is determined based on both the channel width W and a total distance AW traversed vertically (i.e., the depth D3) and laterally (i.e., the divot width W′) by surfaces of the second gate extensions 254B and 254C. Accordingly, the effective channel width W_{eff} can be fine-tuned by adjusting parameters of at least one of the first etching process 50 and the second etching process 52 to achieve varying degrees of the depth D3. In the present embodiments, due to the depth D2 being substantially less than the depth D3 and the divot width W′ of the divots 222 and 224 being substantially constant as described above, the effective channel width W_{eff} is greater than the channel width W.

Subsequently, additional operations may be implemented at operation 32. For example, continuing with the embodiment depicted in FIGS. 13A and 13B as an example and referring to FIGS. 14 and 15, gate spacers 270 may be formed along sidewalls of the first gate structure 244B and gate spacers 272 may be formed along sidewalls of the second gate structure 244C, respectively. The gate spacers 270 and 272 may each include any suitable dielectric material, such as an oxide, a nitride, the like, or combinations thereof. The gate spacers 270 and 272 may be formed by first depositing a dielectric blanket layer over the semiconductor device 200 and subsequently performing an anisotropic etching process to remove portions of the dielectric layer, resulting in the gate spacers 270 and 272. In some embodiments, the gate spacers 270 and 272 each include a multi-layered structure.

Subsequently, source/drain (S/D) structures 260 are formed in the doped region 202D and S/D structure 262 are formed in the doped region 202E by a series of patterning and epitaxial processes. The S/D structures 260 engage with the first gate structure 244B to form a first device (e.g., a field-effect transistor (FET)) F1 and the S/D structures 262 engage with the second gate structure 244C to form a second device F2. The S/D structures 260 and 262 may be formed by etching portions of the doped regions 202D and 202E, respectively, to form S/D recesses (not depicted) and subsequently performing one or more epitaxial growth processes to form the S/D structures 260 and 262 in the respective S/D recesses. The epitaxial growth processes may be implemented using any suitable process, such as metal-organic CVD (MOCVD), molecular beam epitaxy (MBE), liquid phase epitaxy (LPE), vapor phase epitaxy (VPE), selective epitaxial growth (SEG), the like, or combinations thereof. In some embodiments, the S/D structures 260 and 262 are configured to provide devices of the same conductivity type. In some embodiments, the S/D structures 260 and 262 are configured to provide devices of different conductivity types. For example, to provide a p-type device, the S/D structures 260 and/or 262 may include silicon germanium (SiGe) doped with a p-type dopant described above. To provide an n-type device, the S/D structures 260 and/or 262 may include silicon (Si) doped with an n-type dopant described above. S/D structures 260 and 262 may refer to a source or a drain, individually or collectively dependent upon the context.

Thereafter, an interlayer dielectric (ILD) layer (not depicted) may then be formed over the S/D structures 260 and 262 and planarized to expose a top surface of the first gate structure 244B and the second gate structure 244C. If the first gate structure 244B and the second gate structure 244C are configured as dummy gate structures, a gate replacement process may be performed to replace the polysilicon-containing gate electrode 232 with a metal-containing gate electrode described above. In some embodiments, performing the gate replacement process includes depositing and optionally patterning one or more work function metal layers before forming the metal-containing gate electrode. Compositions of the one or more work function metal layers may be selected depending on the conductivity type of the devices F1 and F2. For example, if the device F1 (or F2) is configured as a p-type device (e.g., a PFET), then the work function metal layer(s) may be selected to form a p-type metal gate (PMG). If the device F1 (or F2) is configured as an n-type device (e.g., an NFET), then the work function metal layer(s) may be selected to form an n-type metal gate (NMG). The devices F1 and F2 may be configured to have the same conductivity type. Alternatively, the devices F1 and F2 may be configured to have different conductivity types. Furthermore, the devices F1 and F2 may be formed as transistors of an SRAM cell. It is noted that FIGS. 14 and 15 are for illustration purposes only as they each depict one device formed over the substrate 202. Additional devices formed using the disclosed method 10 over the substrate 202 may include structures similar to the devices F1 and F2.

In the present embodiments, the device F1 formed from the first gate structure 244B may be considered a planar device (e.g., a planar FET), while the device F2 formed from the second gate structure 244C may be considered a quasi-fin-like device (e.g., a quasi-FinFET). Differences in channel width (i.e., the difference between the channel width W and the effective channel width W_{eff} described above) allows the planar and the quasi-FinFET devices be formed over the same substrate such that they can be configured to achieve different performance targets (e.g., low leakage current, high speed, etc.) in an integrated structure (e.g., a multi-transistors SRAM cell). Furthermore, by fine-tuning the depths (e.g., the depths D2 and D3) of the divots formed by the disclosed method 10, devices of varying effective channel width W_{eff} can be formed to achieve such performance targets at varying degrees.

In the present embodiments, the depth D2 is about 0.1 nm to about 1.5 nm, and the depth D3 is about 2.5 nm to about 5.5 nm, giving rise to a ratio of the depth D3 to the depth D2 being about 1.7 to about 55 as described above. If the ratio of the depth D3 to the depth D2 is less than about 1.7, then the structure of the second gate extensions 254B and 254C may not be sufficiently differentiated from the first gate extensions 252B and 252C, and the effect of the second gate extensions 254B and 254C in providing improved device performance (e.g., higher device speed) may not be realized in the semiconductor device 200. If the ratio is greater than about 55, the divots 224 may become too deep (i.e., high aspect ratio) to be fully filled with the various material layers of the gate structure, including the dielectric layer 226, the interfacial layer 228, the gate dielectric layer 230, and the gate electrode 232.

In the present embodiments, the semiconductor device 200 provides both planar and quasi-FinFET devices over the same substrate, thereby affording the flexibility to tune a plurality of devices to have different structures and achieve different device performance suitable for different applications. For example, on the one hand, the planar device (e.g., the device F1; including the first gate extensions 252B and 252C) generally exhibits lower leakage currents and thus better reliability in comparison to the quasi-FinFET device (e.g., the device F2; including the second gate extensions 254B and 254C). On the other hand, improved gate control in the quasi-FinFET device can lead to a higher device speed (e.g., higher current) in comparison to the planar device. In this regard, integrating the planar devices and the quasi-FinFET devices over the same substrate can provide improvement over existing designs that include only planar devices or only quasi-FinFET devices. One such example application includes SRAM cells including multiple transistors of different conductivity types (e.g., n-type or p-type) integrated to meet various design requirements, such as improved read margin and write margin.

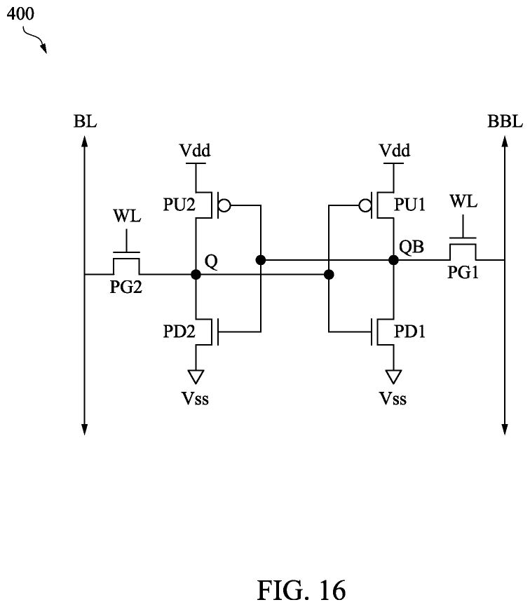

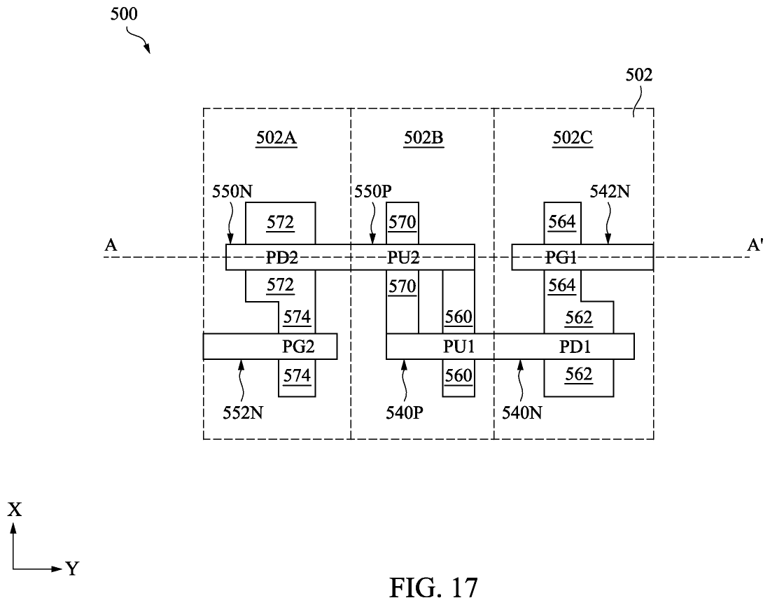

In one example, referring to FIG. 16, a circuit diagram 400 of a memory cell (a memory bit, or a bit cell) 500 is illustrated. In accordance with some embodiments of the present disclosure, the memory cell 500 is configured as an SRAM cell that includes six transistors (6T) and is therefore referred to as a 6T SRAM cell. In some embodiments, the memory cell 500 may be implemented as any of a variety of SRAM cells such as, for example, a two-transistor-two-resistor (2T-2R) SRAM cell, a four-transistor (4T)-SRAM cell, an eight-transistor (8T)-SRAM cell, a ten-transistor (10T)-SRAM cell, etc. Although the discussion of the current disclosure is directed to an SRAM cell, it is understood that other embodiments of the current disclosure can also be used in any of the memory cells such as, for example, dynamic random access (DRAM) memory cells. FIG. 17 depicts an example layout of the memory cell 500, which includes six transistors arranged in a configuration according to the circuit diagram 400.

As shown in FIGS. 16 and 17, the memory cell 500 includes six transistors: PU1, PD1, PU2, PD2, PG1, and PG2. The transistors PU1 and PD1 are formed as a first inverter and the transistors PU2 and PD2 are formed as a second inverter, wherein the first and second inverters are cross-coupled to each other. In some embodiments, referring to FIG. 16, the first and second inverters are coupled between a supply voltage Vdd and the ground Vss. In addition to being coupled to the first and second inverters, the transistors PG1 and PG2 are each coupled to a respective word line (WL). The transistors PG1 and PG2 are further coupled to a bit line (BL) and a bit bar line (BBL), respectively.

In some embodiments, the transistors PU1 and PU2 are referred to as pull-up transistors of the memory cell 500; the transistors PD1 and PD2 are referred to as pull-down transistors of the memory cell 500; and the transistors PG1 and PG2 are referred to as access, or pass gate, transistors of the memory cell 500. In some embodiments, the transistors PD1, PD2, PG1, and PG2 each include an n-type FET (NFET), and PU1 and PU2 each include a p-type FET (PFET). The NFET and PFET are alternatively referred to as n-type metal-oxide-semiconductor (NMOS) transistor and p-type metal-oxide-semiconductor (PMOS) transistor, respectively. In some embodiments, as depicted herein, the memory cell 500 includes four NFETs and two PFETs. In some embodiments, the memory cell 500 includes two NFET and four PFETs. Although the illustrated embodiment of FIG. 17 shows that the transistors of the memory cell 500 are either NFET or PFET, any of a variety of transistors or devices that are suitable for use in a memory device may be implemented as at least one of the transistors such as, for example, a bipolar junction transistor (BJT), a high-electron-mobility transistor (HEMT), etc.

The access transistors PG1 and PG2 have a gate (e.g., gate layer or gate electrode) coupled to their respective WL. The gates of the transistors PG1 and PG2 are configured to receive a pulse signal, through the respective WL to allow or block an access of the memory cell 500 accordingly. The transistors PD1 and PG1 are coupled to each other at Q bar (QB) node with the transistor PD1's drain and the transistor PG1's source. The transistors PD1 and PG2 are coupled to each other at Q node with the transistor PD2's drain and the transistor PG2's source.

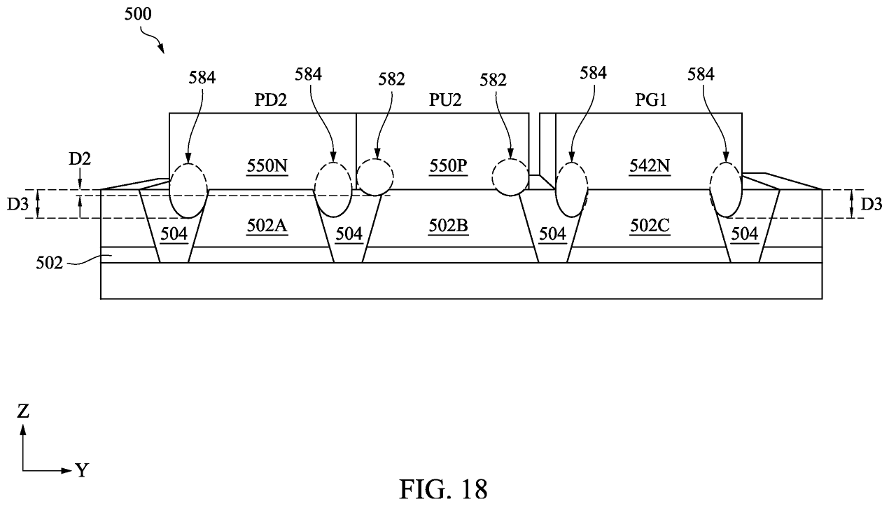

Referring to FIGS. 17-21 collectively, embodiments of the memory cell 500 showing detailed arrangement of various transistors are illustrated. FIG. 17 depicts a schematic top view of an example layout of the memory cell 500, and FIGS. 18-21 each depict a cross-sectional view of the memory cell 500 along line A-A′ of FIG. 17, which extends through the transistors PD2, PU2, and PG1. It is noted that portions of the memory cell 500 may be omitted in one or more of FIGS. 17-21 for purposes of clarity. For example, portions of an isolation structure 504 that separates adjacent transistors are depicted in FIGS. 18-21 but omitted from FIG. 17.

Still referring to FIGS. 17-21 collectively, the memory cell 500 is provided over a substrate 502 that is similar to the substrate 202 described above. The substrate 502 includes a plurality of doped regions (or active regions) 502A, 502B, and 502C laterally separated by isolation structures 504, where the doped regions 502A and 502C are doped with a p-type dopant and configured to provide NFETs, such as the transistors PD1, PD2, PG1, and PG2, and the doped region 502B is doped with an n-type dopant and configured to provide PFETs, such as the transistors PU1 and PU2. In the doped region 502C, a gate structure 540N engages with S/D structures 562 to form the transistor PD1, and a gate structure 542N engages with S/D structures 564 to form the transistor PG1. In the doped region 502B, a gate structure 540P engages with S/D structures 560 to form the transistor PU1, and a gate structure 550P engages with S/D structures 570 to form the transistor PU2. In the doped region 502A, a gate structure 550N engages with S/D structures 572 to form the transistor PD2, and a gate structure 552N engages with S/D structures 574 to form the transistor PG2. In the present embodiments, the gate structures 540N, 540P, 542N, 550N, 550P, and 552N may each be formed over a channel region (not depicted) interposed between a corresponding pair of S/D structures. The gate structures 540N, 540P, 542N, 550N, 550P, and 552N may be similar to the first gate structure 544B or the second gate structure 544C in structure and method of formation (e.g., the method 10), which are described in detail above. The S/D structures 560, 562, 564, 570, 572, and 574 may be formed in their corresponding doped region and similar to the S/D structures 260 or 262 in structure and method of formation (e.g., the method 10), which are described in detail above.

Generally, performance of SRAM devices can be enhanced by improving the read margin and write margin of the memory cells. The read margin can be evaluated based on a β ratio, which is a ratio of the saturation current (Iₛₐₜ) of a transistor PD and the Iₛₐₜ of a transistor PG in a given memory cell (i.e., β=Iₛₐₜ_PD/Iₛₐₜ_PG). The write margin can be evaluated based on a α ratio, which is a ratio of the Iₛₐₜ of a transistor PU to the Iₛₐₜ of the transistor PG in a given memory cell (i.e., α=Iₛₐₜ_PU/Iₛₐₜ_PG). In many instances, increasing the β ratio leads to an increased read margin and decreasing the α ratio leads to an increased write margin. Accordingly, the read margin can be improved by increasing the Iₛₐₜ_PD, decreasing the Iₛₐₜ_PG, or both. Similarly, the write margin can be improved by decreasing the Iₛₐₜ_PU, increasing the Iₛₐₜ_PG, or both. Furthermore, decreasing the Iₛₐₜ_PU and increasing the Iₛₐₜ_PD can lead to improvement in both the read margin and the write margin.

With respect to an SRAM cell such as the memory cell 500, each transistor's Iₛₐₜ can be individually increased by increasing an effective channel width (e.g., W_{eff} of the second gate structure 244C described above) of such transistor, which can be implemented by vertically extending the respective gate structure towards an underlying isolation structure to form a gate extension. In this regard, a deeper gate extension leads to a greater effective channel width, which in turn results in a greater Iₛₐₜ. For example, a planar device (e.g., the device F1) with little to no gate extension (e.g., the depth D2) generally exhibits a lower Iₛₐₜ than a quasi-fin-like device (e.g., the device F2) with a substantial gate extension (e.g., the depth D3). Therefore, using the memory cell 500 as an example, independently tuning the depths of the gate extensions of the transistors PD, PG, and PU can lead to improvement in the read margin, the write margin, or both, in the memory cell 500.

For example, in some embodiments, referring to FIG. 18, the gate structure 550P, corresponding to the transistor PU2, includes first gate extensions 582 extending along sidewalls of the doped region 502B, and the gate structures 550N and 542N, corresponding to the transistors PD2 and PG1, respectively, each include second gate extensions 584 extending along sidewalls of the doped regions 502A and 502C, respectively, into the isolation structures 504. In the present embodiments, the first gate extensions 582 are similar to the first gate extensions 252 and are each defined by the depth D2, and the second gate extensions 584 are similar to the second gate extensions 254 and are each defined by the depth D3, where the depths D2 and D3 are described in detail above. For example, the depth D2 may range from about 0.1 nm to about 1.5 nm, and the depth D3 may range from about 2.5 nm to about 5.5 nm. In this regard, the transistor PU2, being similar to the device F1 described above, is considered a planar device, while the transistors PD2 and PG1, each being similar to the device F2 described above, are considered quasi-fin-like devices. Accordingly, the Iₛₐₜ_PD and Iₛₐₜ_PG are both increased relative to the Iₛₐₜ_PU, leading to an improved read margin (i.e., an increased β ratio).

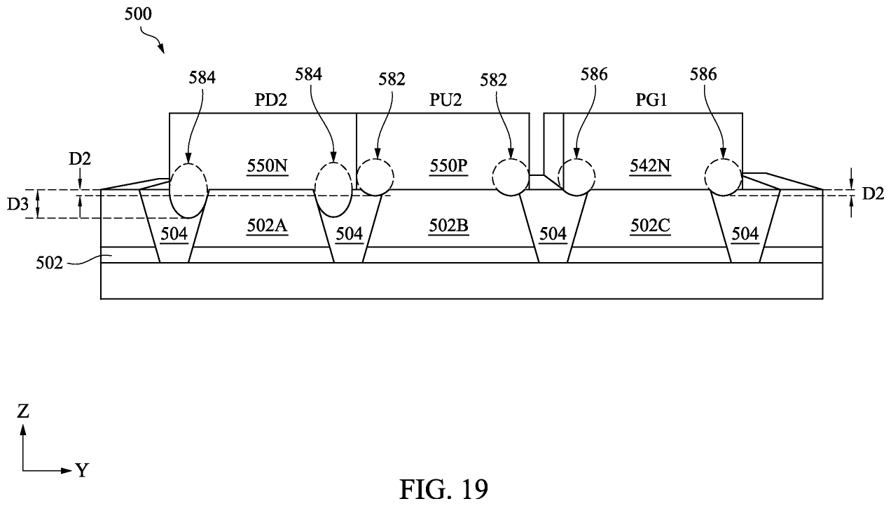

In some embodiments, referring to FIG. 19, the gate structure 550P includes the first gate extensions 582, the gate structure 550N includes the second gate extensions 584, and the gate structure 542N includes third gate extensions 586 extending along the sidewalls of the doped region 502C into the isolation structures 504. In the present embodiments, the third gate extensions 586 are similar to the first gate extensions 252 and are each defined by the depth D2. In this regard, the transistors PU2 and PG1, each being similar to the device F1 described above, are considered planar devices, while the transistor PD2, being similar to the device F2 described above, is considered a quasi-fin-like device. Accordingly, the Iₛₐₜ_PD is increased relative to both the Iₛₐₜ_PG and the Iₛₐₜ_PU, leading to an improved read margin (i.e., an increased β ratio).

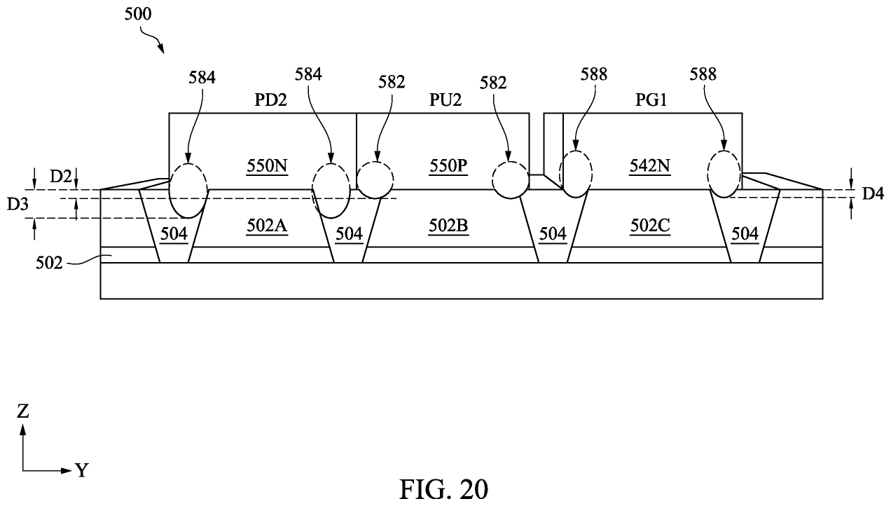

In some embodiments, referring to FIG. 20, the gate structure 550P includes the first gate extensions 582, the gate structure 550N includes the second gate extensions 584, and the gate structure 542N includes fourth gate extensions 588 extending along the sidewalls of the doped region 502C into the isolation structures 504. In the present embodiments, the fourth gate extensions 588 are similar to the second gate extensions 584 and defined by a depth D4. In the present embodiments, the depth D4 is greater than the depth D2 but less than the depth D3. For example, the depth D4 may range from about 2.5 nm to about 5.5 nm, where a ratio of the depth D3 to the depth D4 may range from about 1.04 to about 2.2. In this regard, the transistor PU2, being similar to the device F1 described above, is considered a planar device, while the transistors PD2 and PG1, each being similar to the device F2 described above, are considered quasi-fin-like devices, though their respective gate extensions have different depths. Accordingly, the Iₛₐₜ_PD and Iₛₐₜ_PG are both increased relative to the Iₛₐₜ_PU, though the increase in Iₛₐₜ_PD is greater than the increase in Iₛₐₜ_PG, leading to an improved read margin (i.e., an increased β ratio).

In some embodiments, if the ratio of the depth D3 to the depth D4 is less than about 1.04, then the increase in Iₛₐₜ may not be significant enough to result in an improvement in the read margin. On the other hand, if the ratio is greater than 2.2, then the process of forming the fourth gate extensions 588 may suffer processing limitations, such as challenging material deposition in divots of high aspect ratios.

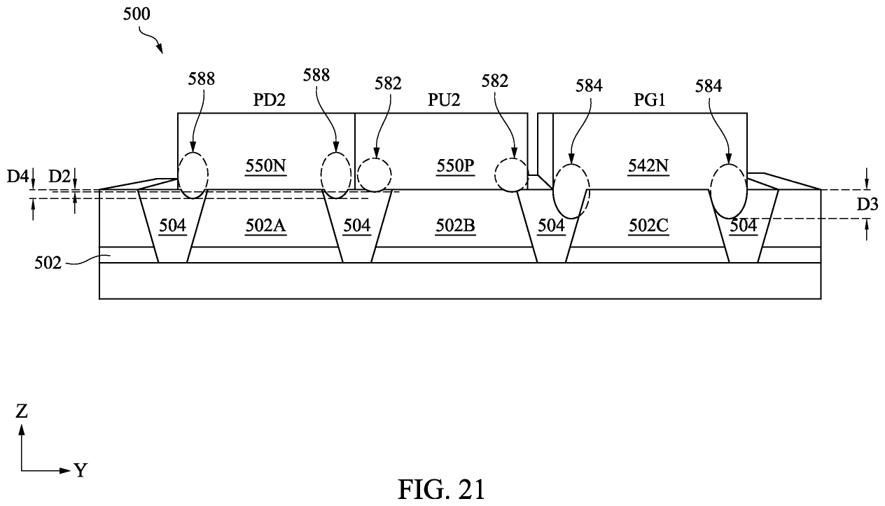

In some embodiments, referring to FIG. 21, the gate structure 550P includes the first gate extensions 582, the gate structure 542N includes the second gate extensions 584, and the gate structure 550N includes the fourth gate extensions 588 described above. In this regard, the transistor PU2, being similar to the device F1 described above, is considered a planar device, while the transistors PD2 and PG1, each being similar to the device F2 described above, are considered quasi-fin-like devices, though their respective gate structures include gate extensions of different depths. Accordingly, the Iₛₐₜ_PD and Iₛₐₜ PG are both increased relative to the Iₛₐₜ_PU, though the increase in Iₛₐₜ PG is greater than the increase in Iₛₐₜ PD, leading to an improved write margin (i.e., a decreased a ratio).

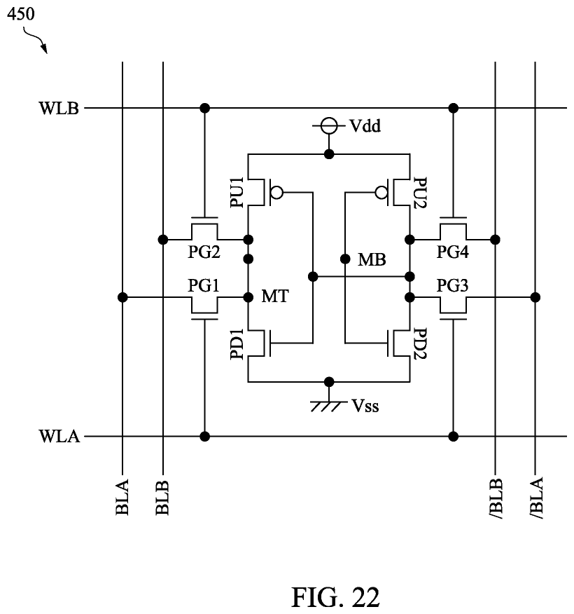

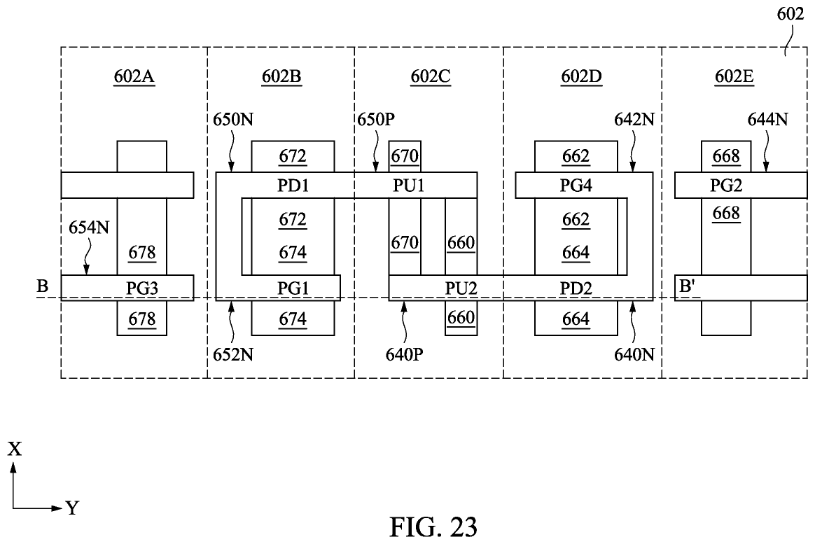

In another example, referring to FIG. 22, a circuit diagram 450 of a memory cell (a memory bit, or a bit cell) 600 is illustrated. In accordance with some embodiments of the present disclosure, the memory cell 600 is configured as an SRAM cell that includes eight transistors (8T) and is therefore referred to as an 8T SRAM cell. FIG. 23 depicts an example layout of the memory cell 600, which includes eight transistors arranged in a configuration according to the circuit diagram 450. Although the depicted memory cell 600 is an 8T two read/write (2RW) dual-port memory cell, the present embodiments are also applicable to other configurations of 8T SRAM cells.

As shown in FIGS. 22 and 23, the memory cell 600 includes eight transistors: PU1, PD1, PU2, PD2, PG1, PG2, PG3, and PG4. In some embodiments, the transistors PU1 and PU2 are referred to as pull-up transistors of the memory cell 600; the transistors PD1 and PD2 are referred to as pull-down transistors of the memory cell 600; and the transistors PG1, PG2, PG3, and PG4 are referred to as access, or pass gate, transistors of the memory cell 600, where the pull-up, the pull-down, and the access transistors are similar to those described above with respect to the memory cell 500. The transistors PU1 and PD1 are formed as a first inverter and the transistors PU2 and PD2 are formed as a second inverter, wherein the first and second inverters are cross-coupled to each other. In some embodiments, referring to FIG. 22, the first and second inverters are coupled between a supply voltage Vdd and the ground Vss. In addition to being coupled to the first and second inverters, the transistors PG1 and PG3 are coupled to a word line WLA and the transistors PG2 and PG4 are coupled to a word line WLB. The transistors PG1, PG3, PG2, and PG4 are further coupled to a bit line BLA, a bit bar line/BLA, a bit line BLB, and a bit bar line/BLB, respectively.

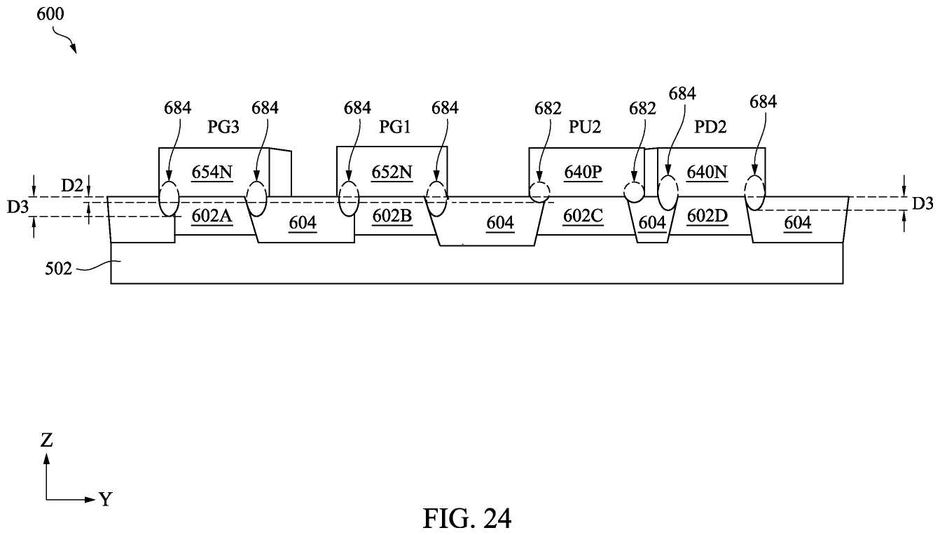

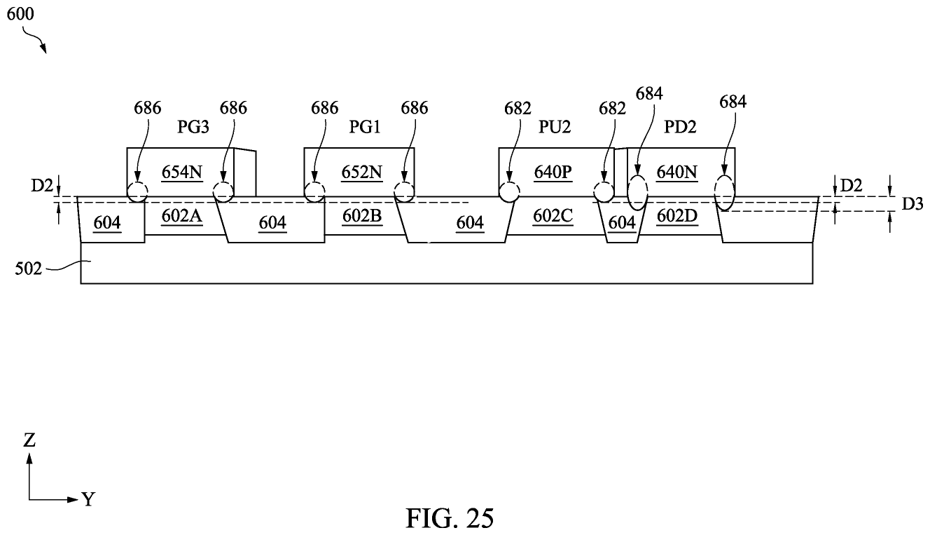

Referring to FIGS. 23-27 collectively, embodiments of the memory cell 600 showing detailed arrangement of various transistors is illustrated. FIG. 23 depicts a schematic top view of an example layout of the memory cell 600, and FIGS. 24-27 each depict a cross-sectional view of the memory cell 500 along line B-B′ of FIG. 23, which extends through the transistors PG3, PG1, PU2, and PD2. It is noted that portions of the memory cell 600 may be omitted in one or more of FIGS. 23-27 for purposes of clarity. For example, portions of an isolation structure 604 that separates adjacent transistors are depicted in FIGS. 24-27 but omitted from FIG. 23.

Still referring to FIGS. 23-27 collectively, the memory cell 600 is provided over a substrate 602 that is similar to the substrate 202 described above. The substrate 602 includes a plurality of doped regions (or active regions) 602A, 602B, 602C, 602D, and 602E laterally separated by isolation structures 604, where the doped regions 602A, 602B, 602D, and 602E are doped with a p-type dopant and configured to provide NFETs, such as PD1, PD2, PG1, PG2, PG3, and PG4, and the doped region 602C is doped with an n-type dopant and configured to provide PFETs, such as PU1 and PU2. In the doped region 602A, a gate structure 654N engages with S/D structures 678 to form the transistor PG3. In the doped region 602B, a gate structure 650N engages with S/D structures 672 to form the transistor PD1, and a gate structure 652N engages with S/D structures 674 to form the transistor PG1. In the doped region 602C, a gate structure 650P engages with S/D structures 670 to form the transistor PU1, and a gate structure 640P engages with S/D structures 660 to form the transistor PU2. In the doped region 602D, a gate structure 642N engages with S/D structures 662 to form the transistor PG4, and a gate structure 640N engages with S/D structures 664 to form the transistor PD2. In the doped region 602E, a gate structure 644N engages with S/D structures 668 to form the transistor PG2. In the present embodiments, the gate structures 640N, 642N, 644N, 640P, 650P, 650N, 652N, and 654N may each be formed over a channel region (not depicted) interposed between a corresponding pair of S/D structures. The gate structures 640N, 642N, 644N, 640P, 650P, 650N, 652N, and 654N may be similar to the first gate structure 544B or the second gate structure 544C in structure and method of formation (e.g., the method 10), which are described in detail above. The S/D structures 660, 662, 664, 668, 670, 672, 674, and 678 may be formed in their corresponding doped region and similar to the S/D structures 260 or 262 in structure and method of formation (e.g., the method 10), which are described in detail above.

Similar to the memory cell 500 described above, independently tuning the depths of the gate extensions of the transistors PD, PG, and PU in the memory cell 600 can lead to improvement in the read margin, the write margin, or both, in the memory cell 600. For example, in some embodiments, referring to FIG. 24, the gate structure 640P, corresponding to the transistor PU2, includes first gate extensions 682 extending along sidewalls of the doped region 602C, and the gate structures 654N, 652N, and 640N, corresponding to the transistors PG3, PG1, and PD2, respectively, each include second gate extensions 684 extending along sidewalls of the doped regions 602A, 602B, and 602D, respectively, into the isolation structures 604. In the present embodiments, the first gate extensions 682 are similar to the first gate extensions 252 and are each defined by the depth D2, and the second gate extensions 684 are similar to the second gate extensions 254 and are each defined by the depth D3, where the depths D2 and D3 are described in detail above. For example, the depth D2 may range from about 0.1 nm to about 1.5 nm, and the depth D3 may range from about 2.5 nm to about 5.5 nm. In this regard, the transistor PU2, being similar to the device F1 described above, is considered a planar device, while the transistors PG3, PG1, and PD2, each being similar to the device F2 described above, are considered quasi-fin-like devices. Accordingly, the Iₛₐₜ_PD and Iₛₐₜ_PG are both increased relative to the Iₛₐₜ_PU, leading to an improved read margin (i.e., an increased β ratio).

In some embodiments, referring to FIG. 25, the gate structure 640P includes the first gate extensions 682, the gate structure 640N includes the second gate extensions 684, and the gate structures 654N and 652N each include third gate extensions 686 extending along the sidewalls of the doped regions 602A and 602B, respectively, into the isolation structures 604. In the present embodiments, the third gate extensions 686 are similar to the first gate extensions 252 and are each defined by the depth D2. In this regard, the transistors PG3, PG1, and PU2, each being similar to the device F1 described above, are considered planar devices, while the transistor PD2, being similar to the device F2 described above, is considered a quasi-fin-like device. Accordingly, the Iₛₐₜ_PD is increased relative to both the Iₛₐₜ_PG and the Iₛₐₜ_PU, leading to an improved read margin (i.e., an increased β ratio).

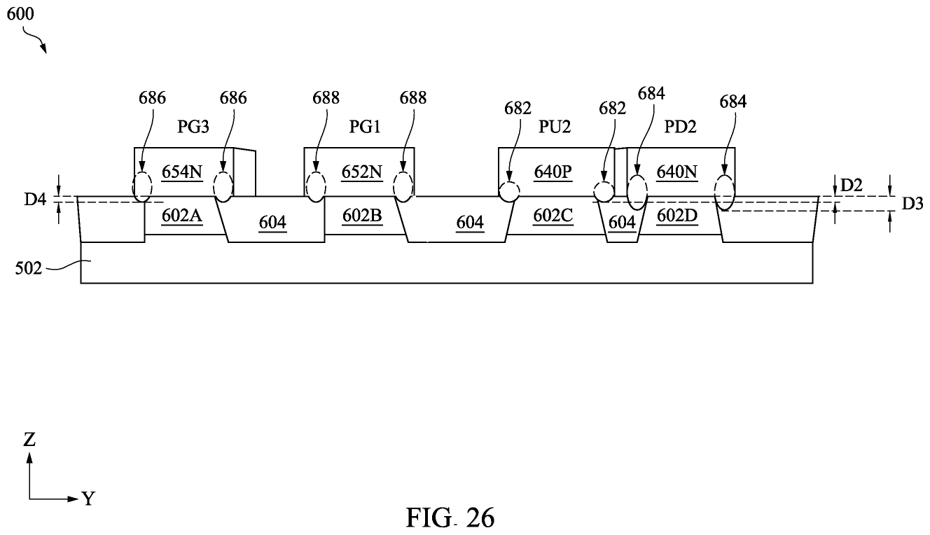

In some embodiments, referring to FIG. 26, the gate structure 640P includes the first gate extensions 682, the gate structure 640N includes the second gate extensions 684, and the gate structures 654N and 652N each include fourth gate extensions 688 extending along the sidewalls of the doped regions 602A and 602B, respectively, into the isolation structures 604. In the present embodiments, the fourth gate extensions 688 are similar to the second gate extensions 684 and defined by the depth D4, which has been described in detail above with respect to the memory cell 500. For example, the depth D4 is greater than the depth D2 but less than the depth D3. In some embodiments, the depth D4 ranges from about 2.5 nm to about 5.5 nm, where a ratio of the depth D3 to the depth D4 may range from about 1.04 to about 2.2. Significance of such a range is described in detail above with respect to the memory cell 500. In this regard, the transistor PU2, being similar to the device F1 described above, is considered a planar device, while the transistors PG3, PG1, and PD2, each being similar to the device F2 described above, are considered quasi-fin-like devices, though their respective gate extensions have different depths. Accordingly, the Iₛₐₜ_PD and Iₛₐₜ_PG are both increased relative to the Iₛₐₜ_PU, though the increase in Iₛₐₜ_PD is greater than the increase in Iₛₐₜ_PG, leading to an improved read margin (i.e., an increased β ratio).

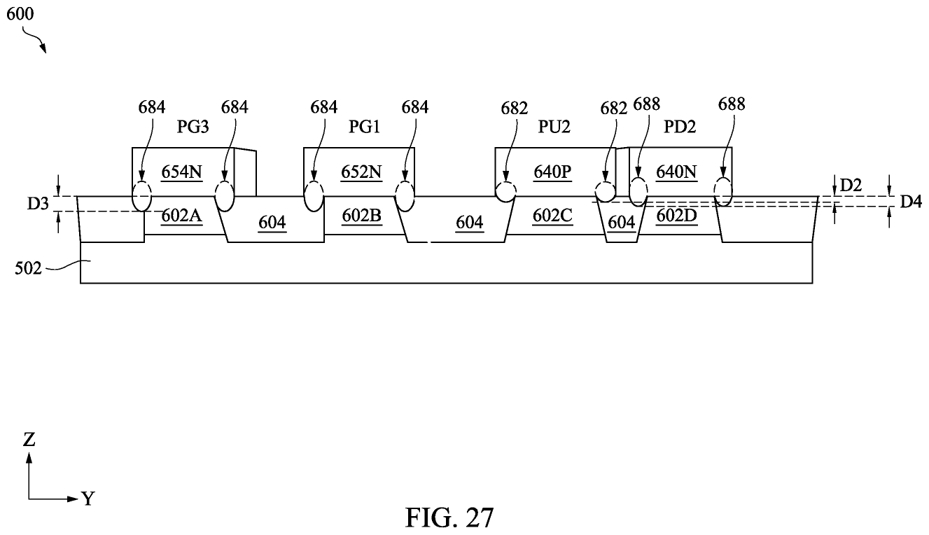

In some embodiments, referring to FIG. 27, the gate structure 640P includes the first gate extensions 682, the gate structures 654N and 652N each include the second gate extensions 684, and the gate structure 640N includes the fourth gate extensions 688 described above. In this regard, the transistor PU2, being similar to the device F1 described above, is considered a planar device, while the transistors PG3, PG1, and PD2, each being similar to the device F2 described above, are considered quasi-fin-like devices, though their respective gate extensions have different depths. Accordingly, the Iₛₐₜ_PD and Iₛₐₜ_PG are both increased relative to the Iₛₐₜ_PU, though the increase in Iₛₐₜ_PG is greater than the increase in Iₛₐₜ_PD, leading to an improved write margin (i.e., a decreased a ratio).

One aspect of this description relates to a method of fabricating a semiconductor structure. The method can include providing a substrate including a doped region. The method can include forming a first isolation structure and a second isolation structure in the substrate along respective sidewalls of the doped region. The method can include performing a first etching process to form a first divot in the first isolation structure and a second divot in the second isolation structure, where the first divot and the second divot each have a first depth measured from a top surface of the substrate and each extending along the respective sidewalls of the doped region. The method can include forming a patterned mask over the first divot to expose the second divot. The method can include performing a second etching process to deepen the second divot to a second depth. The method can further include forming a gate structure over the substrate, which results in a first gate extension in the first divot and a second gate extension in the second divot.

Another aspect of this description relates to semiconductor structure. The semiconductor structure can include a first isolation structure and a second isolation structure disposed in a substrate. The semiconductor structure can include a doped region interposed between the first isolation structure and the second isolation structure in the substrate. The semiconductor structure can include a gate structure disposed over the doped region. The semiconductor structure can include a first gate extension protruding from the gate structure into the first isolation structure, where the first gate extension has a first depth measured from a top surface of the substrate. The semiconductor structure can further include a second gate extension protruding from the gate structure into the second isolation structure, where the second gate extension has a second depth that is different from the first depth.

Another aspect of this description relates to a semiconductor structure. The semiconductor structure can include a first active region and a second active region disposed in a substrate. The semiconductor structure can include an isolation structure interposed between the first active region and a second active region. The semiconductor structure can include a first gate structure disposed over the first active region. The semiconductor structure can include a first gate extension extending from the first gate structure into the isolation structure, where the first gate extension has a first depth. The semiconductor structure can include a second gate structure disposed over the second active region. The semiconductor structure can further include a second gate extension extending from the second gate structure into the isolation structure, where the second gate extension has a second depth that is greater than the first depth.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
providing a substrate including a doped region;
forming a first isolation structure and a second isolation structure in the substrate along respective sidewalls of the doped region;
performing a first etching process to form a first divot in the first isolation structure and a second divot in the second isolation structure, the first divot and the second divot each having a first depth measured from a top surface of the substrate and each extending along the respective sidewalls of the doped region;
forming a patterned mask over the first divot to expose the second divot;
performing a second etching process to deepen the second divot to a second depth; and
forming a gate structure over the substrate, resulting in a first gate extension in the first divot and a second gate extension in the second divot.

2. The method of claim 1, wherein the patterned mask is a first patterned mask, the method further comprising:
forming an oxide layer over the substrate after forming the first isolation structure and the second isolation structure; and
forming a second patterned mask over the oxide layer to expose a portion of the oxide layer over the first isolation structure and the second isolation structure before performing the first etching process, wherein performing the first etching process removes the exposed portion of the oxide layer, thereby exposing the first isolation structure and the second isolation structure.

3. The method of claim 2, wherein performing the first etching process forms a third divot having the first depth, the method further comprising:
forming a third patterned mask over the first divot and the second divot; and
performing a third etching process to deepen the third divot to a third depth, wherein the third depth is greater than the first depth but less than the second depth, and wherein forming the gate structure results in a third gate extension in the third divot.

4. The method of claim 1, wherein the first etching process is performed using a wet etchant of a first concentration and the second etching process is performed using the wet etchant of a second concentration that is greater than the first concentration.

5. The method of claim 4, wherein the wet etchant includes hydrofluoric acid.

6. The method of claim 1, wherein the first etching process is performed for a first duration and the second etching process is performed for a second duration that is greater than the first duration.

7. The method of claim 1, wherein forming the gate structure includes:
forming an interfacial layer over the first divot and the second divot;
forming a gate dielectric layer over the interfacial layer; and
forming a gate electrode over the gate dielectric layer.

8. The method of claim 1, wherein the gate structure traverses a channel of the doped region, the method further comprising:
forming gate spacers along sidewalls of the gate structure; and
forming a pair of source/drain structures in the doped region such that the channel is interposed between the source/drain structures.

9. A semiconductor structure, comprising:
a first isolation structure and a second isolation structure disposed in a substrate;
a doped region interposed between the first isolation structure and the second isolation structure in the substrate;
a gate structure disposed over the doped region;
a first gate extension protruding from the gate structure into the first isolation structure, the first gate extension having a first depth measured from a top surface of the substrate; and
a second gate extension protruding from the gate structure into the second isolation structure, the second gate extension having a second depth measured from the top surface of the substrate, the second depth being different from the first depth.

10. The semiconductor structure of claim 9, wherein the first gate extension and the second gate extension each have a width that ranges from 20 nm to 25 nm.

11. The semiconductor structure of claim 9, wherein the first depth ranges from 0.1 nm to 1.5 nm.

12. The semiconductor structure of claim 9, wherein the second depth ranges from 2.5 nm to 5.5 nm.

13. The semiconductor structure of claim 9, wherein a ratio of the second depth to the first depth is 1.7 to 55.

14. The semiconductor structure of claim 9, further comprising:
a second doped region in the substrate;
a third isolation structure adjacent the second doped region;
a third gate structure over the second doped region; and
a third gate extension protruding from the third gate structure into the third isolation structure, the third gate extension having a third depth that is greater than the first depth but less than the second depth.

15. The semiconductor structure of claim 9, wherein the gate structure includes:
an oxide layer over the doped region;
a gate dielectric layer over the oxide layer; and
a gate electrode over the gate dielectric layer, wherein the first gate extension and the second gate extension includes at least one of the oxide layer, the gate dielectric layer, and the gate electrode.

16. A semiconductor structure, comprising:
a first active region and a second active region disposed in a substrate;
an isolation structure interposed between the first active region and the second active region;
a first gate structure disposed over the first active region;
a first gate extension extending from the first gate structure into the isolation structure, the first gate extension having a first depth;
a second gate structure disposed over the second active region; and
a second gate extension extending from the second gate structure into the isolation structure, the second gate extension having a second depth that is greater than the first depth.

17. The semiconductor structure of claim 16, further comprising:
first source/drain (S/D) structures engaged with the first gate structure to form a first transistor; and
second S/D structures engaged with the second gate structure to form a second transistor.

18. The semiconductor structure of claim 17, wherein the first transistor is configured as a pull-up transistor and the second transistor is configured as a pull-down transistor, the pull-up transistor and the pull-down transistor forming an inverter in a static random-access memory (SRAM) cell.

19. The semiconductor structure of claim 17, wherein the first transistor is configured as a pull-up transistor and the second transistor is configured as a pass-gate transistor in a static random-access memory (SRAM) cell.

20. The semiconductor structure of claim 16, wherein a ratio of the second depth to the first depth is 1.7 to 55.
